(19) United States
(12) Patent Application Publication
(10) Pub. No.: US 2024/0008292 A1
(43) Pub. Date: Jan. 4, 2024

(54) NEUROMORPHIC MEMORY ELEMENT SIMULTANEOUSLY IMPLEMENTING VOLATILE AND NON-VOLATILE FEATURE FOR EMULATION OF NEURON AND SYNAPSE

(71) Applicant: Samsung Electronics Co., Ltd., Suwon-si (KR)

(72) Inventors: Keon Jae Lee, Daejeon (KR); Sang Hyun Sung, Daejeon (KR); Young Hoon Jung, Daejeon (KR)

(73) Assignee: Korea Advanced Institute of Science and Technology, Daejeon (KR)

(21) Appl. No.: 18/299,811

(22) Filed: Apr. 13, 2023

(30) Foreign Application Priority Data
Jul. 1, 2022 (KR) 10-2022-0081489
Aug. 25, 2022 (KR) 10-2022-0106915

(51) Int. Cl. H10B 63/00; H10B 63/10; H10N 70/20; H10N 70/00; G06N 3/063

(52) U.S. Cl. CPC H10B 63/82; H10B 63/10; H10N 70/231; H10N 70/24; H10N 70/841; H10N 70/8828; H10N 70/883; H10N 70/026; G06N 3/063

(57) ABSTRACT

Disclosed is a neuromorphic memory element, which includes a first electrode; a second electrode; a first thin film layer adjacent to the first electrode between the first electrode and the second electrode and that is configured to emulate a neuronal plasticity by performing a volatile storage function based on a voltage difference between the first electrode and the second electrode; and a second thin film layer between the first thin film layer and the second electrode and that is configured to emulate a synaptic plasticity by performing a non-volatile storage function.

### CROSS-REFERENCE TO RELATED APPLICATIONS

This application claims priority under 35 U.S.C. § 119 to Korean Patent Application No. 10-2022-0081489 filed on Jul. 1, 2022, and Korean Patent Application No. 10-2022-0106915 filed on Aug. 25, 2022, in the Korean Intellectual Property Office, the disclosures of which are incorporated by reference herein in their entireties.

### BACKGROUND

Embodiments of the present disclosure relate to a neuromorphic memory element, and more particularly, relate to a neuromorphic memory element that simultaneously implements volatile and non-volatile features for emulation of neurons and synapses.

With the advent of the big data era, the demand for computing, processing, and storing vast amounts of data is increasing. A Von Neumann structure, previously used in computer systems, is a structure in which a central processing unit that processes and calculates data and a memory that stores processed and calculated data are separated from each other. In such a structure, bottlenecks and energy consumption occurring in the data exchange process between the central processing unit and the memory due to an increase in the amount of data in the era of big data are emerging as issues that may need to be resolved.

As a solution to these problems of existing computer systems, attempts are being made to implement a system that imitates the human brain, which is called neuromorphic computing. Unlike conventional Von Neumann computing, deep neural networks, which may be an example of neuromorphic computing systems, use synapses with specific synaptic weights connected in parallel and neurons that transfer them to the next synapse. When calculations are performed based on the structure of the deep neural networks, accurate and fast learning and inference may be performed with efficient energy consumption.

Most of these deep neural networks have been studied in the context of processing data using software. However, to implement true ultra-low-power neuromorphic computing, suitable hardware may be desirable, and it may be further desirable to secure synapse and neuron elements capable of parallel operation from the element level and having energy efficiency.

### SUMMARY

Embodiments of the present disclosure provide a neuromorphic memory element that implements volatile and non-volatile features together in one element for emulation of neurons and synapses.

According to an embodiment of the present disclosure, a neuromorphic memory element includes a first electrode; a second electrode; a first thin film layer adjacent to the first electrode between the first electrode and the second electrode and that emulates a neuronal plasticity by performing a volatile storage function based on a voltage difference between the first electrode and the second electrode; and a second thin film layer between the first thin film layer and the second electrode and that emulates a synaptic plasticity by performing a non-volatile storage function.

According to an embodiment, the first thin film layer may be configured to form a filament based on a magnitude of the voltage difference applied between the first electrode and the second electrode, and the second thin film layer may be configured to undergo a phase change based on a voltage pulse applied between the first electrode and the second electrode.

According to an embodiment, the first thin film layer may be configured to form the filament when the voltage difference applied between the first electrode and the second electrode is greater than a threshold voltage, and may be configured to decompose the filament when the voltage difference applied between the first electrode and the second electrode is less than the threshold voltage.

According to an embodiment, the second thin film layer may be configured to change phase to a crystal state when a setting signal having a first magnitude and a first width is applied between the first electrode and the second electrode, and may be configured to change phase to an amorphous state when a reset signal having a second magnitude greater than the first magnitude and a second width less than the first width is applied between the first electrode and the second electrode.

According to an embodiment, the first thin film layer may have a different rate of formation or decomposition of the filament based on a phase change state of the second thin film layer when a capacitor is connected to the first electrode and the second electrode in parallel with the first thin layer and the second thin layer.

According to an embodiment, the second thin film layer may have a different phase change rate based on whether the filament is formed in the first thin film layer when a capacitor is connected in parallel to the first electrode and the second electrode.

According to an embodiment, when the filament is not formed in the first thin film layer and the first thin film layer is in the amorphous state, the second thin film layer and the second thin film layer may have a first resistance state.

According to an embodiment, when the filament is not formed in the first thin film layer and the first thin film layer is in the crystal state, the second thin film layer and the second thin film layer may have a second resistance state less than the first resistance state.

According to an embodiment, when the filament is formed in the first thin film layer and the first thin film layer is in an amorphous state, the second thin film layer and the second thin film layer may have a third resistance state less than the first resistance state.

According to an embodiment, when the filament is formed in the first thin film layer and the first thin film layer is in a crystal state, the second thin film layer and the second thin film layer may have a fourth resistance state less than the second resistance state and the third resistance state.

According to an embodiment of the present disclosure, a neuromorphic memory element includes a first electrode; a second electrode; a threshold switching portion stacked on the first electrode and that is turned on or turned off based on a voltage difference between the first electrode and the second electrode; and a phase change memory portion stacked between the first electrode and the threshold switching portion and that is configured to change phase based on a voltage pulse applied between the first electrode and the second electrode.

According to an embodiment, the threshold switching portion may comprise a thin film doped with silver (Ag) in silicon dioxide (SiO2).

According to an embodiment, the threshold switching portion may form a silver filament to lower a resistance thereof when the voltage difference applied between the first electrode and the second electrode is greater than a threshold voltage.

According to an embodiment, the phase change memory portion may include a GST (Ge, Sb, and Te) material or an AIST (Ag, In, Sb, and Te) material.

According to an embodiment, the phase change memory portion may be configured to change phase from an amorphous state to a crystal state to lower a distance thereof based on the voltage pulse.

According to an embodiment, the threshold switching portion may have two resistance states based on the voltage difference between the first electrode and the second electrode, and the phase change memory portion may have two resistance states based on a phase change state.

According to an embodiment, the first electrode may comprise gold (Au).

According to an embodiment, the second electrode may be comprise a tungsten titanium compound.

According to an embodiment of the present disclosure, a neuromorphic memory element includes a first electrode; a second electrode; a threshold switching portion stacked on the first electrode and that is turned on or turned off based on a voltage difference between the first electrode and the second electrode; and a resistance change memory portion stacked between the first electrode and the threshold switching portion and that is configured to change resistance based on a voltage applied between the first electrode and the second electrode.

According to an embodiment, the threshold switching portion may comprise an oxide doped with copper (Cu), and the resistance change memory portion may include a ferroelectric tunnel junction (FTJ) element using a ferroelectric or a magnetic random access memory (MRAM).

### BRIEF DESCRIPTION OF THE FIGURES

A detailed description of each drawing is provided to facilitate a more thorough understanding of the drawings referenced in the detailed description of the present disclosure.

FIG. 1 is a diagram illustrating a neuromorphic memory element, according to an embodiment.

FIG. 2 is a three-dimensional diagram of the neuromorphic memory element of FIG. 1.

FIG. 3 is a diagram illustrating a comparison of an operation of neurons of brain cells and an operation of a first thin film layer of FIG. 1 according to an embodiment.

FIG. 4 is a diagram illustrating a comparison of an operation of synapses of brain cells and an operation of a second thin film layer of FIG. 1 according to an embodiment.

FIG. 5 is a graph illustrating a voltage and a current (or resistance state) between a first electrode and a second electrode according to a state change of a first thin film layer of FIG. 1.

FIG. 6 is a graph illustrating a voltage and a current (or resistance state) between a first electrode and a second electrode according to a state change of a second thin film layer of FIG. 1.

FIG. 7 is a graph illustrating a resistance state of a neuromorphic memory element of FIG. 1.

FIG. 8 is a diagram illustrating states of a neuromorphic memory element of FIG. 1 corresponding to a graph of FIG. 7.

FIG. 9 is a diagram illustrating a circuit including a neuromorphic memory element of FIG. 1 for verifying a feature emulation of neurons.

FIG. 10 is graphs illustrating a feature emulation of neurons verified by a circuit of FIG. 9.

FIG. 11 is a diagram illustrating a learning process of a general spiking neural network (SNN), according to an embodiment.

FIG. 12 is a diagram illustrating a learning process of a neuromorphic memory array including a neuromorphic memory element of FIG. 1.

FIG. 13 is a diagram illustrating a manufacturing process of a neuromorphic memory element of FIG. 1.

### DETAILED DESCRIPTION

Hereinafter, embodiments of the inventive concept will be described in detail with reference to the accompanying drawings. The same reference numerals are used for the same components in the drawings, and redundant descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

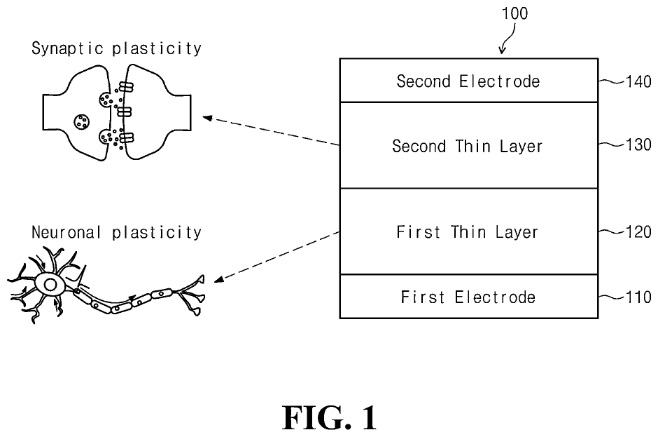

FIG. 1 is a diagram illustrating a neuromorphic memory element, according to an embodiment. Referring to FIG. 1, a neuromorphic memory element 100 may include a first electrode 110, a first thin film layer 120, a second thin film layer 130, and a second electrode 140.

According to an embodiment, the first electrode 110, the first thin film layer 120, the second thin film layer 130, and the second electrode 140 may be arranged in a stacked formation. For example, the first thin film layer 120 and the second thin film layer 130 may be stacked between the first electrode 110 and the second electrode 140. The first thin film layer 120 may be stacked between the first electrode 110 and the second thin film layer 130 to be adjacent to the first electrode 110. The second thin film layer 130 may be stacked between the first thin film layer 120 and the second electrode 140 to be adjacent to the second electrode 140.

According to an embodiment, the first thin film layer 120 may be configured to emulate the plasticity of neurons among human brain cells. For example, the first thin film layer 120 may be configured to form a filament between the second thin film layer 130 and the first electrode 110 based on a voltage difference between the first electrode 110 and the second electrode 140. When a voltage is not applied between the first electrode 110 and the second electrode 140, the first thin film layer 120 may have an initial state in which filaments are not formed. When a voltage exceeding a specified voltage (e.g., a threshold voltage) is applied between the first electrode 110 and the second electrode 140, the first thin film layer 120 may be configured to form a filament. When a voltage equal to or less than a specified voltage is applied between the first electrode 110 and the second electrode 140, the filament of the first thin film layer 120 may be configured to return to an initial state again. Accordingly, the first thin film layer 120 has features of a volatile memory and may operate as a threshold switch that is turned on or off according to the threshold voltage. In addition, a strength of the filament of the first thin film layer 120 may vary based on a frequency of voltage application between the first electrode 110 and the second electrode 140. The filament of the first thin film layer 120 may be formed more quickly when a voltage greater than a threshold voltage is previously applied between the first electrode 110 and the second electrode 140. Accordingly, the first thin film layer 120 may emulate the plasticity of neurons that make period jumps according to the degree of excitation.

According to an embodiment, the second thin film layer 130 may be configured to emulate the plasticity of synapses among human brain cells. For example, the second thin film layer 130 may include a phase change material. The second thin film layer 130 may be heated by a voltage pulse transferred through a filament of the first thin film layer 120 and may be configured to undergo a phase change between amorphous and crystal phases responsive to heating by the voltage pulse. Accordingly, a resistance of the second thin film layer 130 may increase or decrease according to the phase change, and may emulate a change in synaptic connection strength based on the increase or decrease in the resistance.

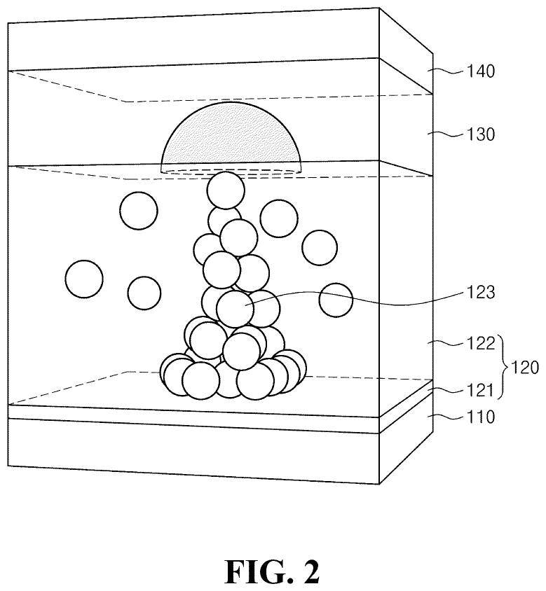

FIG. 2 is a three-dimensional diagram of the neuromorphic memory element of FIG. 1. Referring to FIG. 2, the neuromorphic memory element 100 may include the first electrode 110, the first thin film layer 120, the second thin film layer 130, and the second electrode 140.

According to an embodiment, the first electrode 110 may be made of a metal material on which the first thin film layer 120 may be deposited. For example, the first electrode 110 may be made of gold (Au). For example, the first electrode 110 may be formed to a thickness of 35 to 45 nm.

According to an embodiment, the first thin film layer 120 may include a threshold switching element. For example, the first thin film layer 120 may be formed of a volatile memristor element based on electrochemical metallization. The first thin film layer 120 may be formed by doping silver (Ag) into a silicon dioxide (SiO₂) matrix (e.g., Ag:SiO₂). For example, the first thin film layer 120 may include a source layer 121 and a doped layer 122. The source layer 121 may ensure that the doped layer 122 adheres well to the first electrode 110. The source layer 121 may be formed to a thickness of 1 to 10 nm. In other embodiments, the source layer 121 may be formed to a thickness of 10 to 100 nm when used as an electrode. The doped layer 122 may be formed to a thickness of 5 to 50 nm. The doped layer 122 may include silver (Ag) in an amount of 5 to 30%. The ratio of silver (Ag) in the doped layer 122 may be adjusted according to the thickness of the doped layer 122 or voltage conditions used.

According to an embodiment, the first thin film layer 120 may be formed by doping various oxides. For example, the oxide of the first thin film layer 120 may include HfO₂, MgO₂, or WO₃. The first thin film layer 120 may be formed by doping an oxide with copper (Cu).

According to an embodiment, the first thin film layer 120 may be configured to perform a threshold switching operation. For example, the first thin film layer 120 may be configured to form a filament 123 based on a voltage between the first electrode 110 and the second electrode 140. The filament 123 may be formed when a voltage between the first electrode 110 and the second electrode 140 exceeds a threshold voltage. When the voltage between the first electrode 110 and the second electrode 140 drops below the threshold voltage, the filament 123 may return to a molecular state. Thus, the first thin film layer 120 may operate as a volatile memory. The time for forming the filament 123 may be shortened as the number of times the voltage between the first electrode 110 and the second electrode 140 exceeds the threshold voltage increases.

According to an embodiment, the second thin film layer 130 may include a phase change memory element. For example, the second thin film layer 130 may be made of a GST (Ge, Sb, Te) phase change material. Ge, Sb, and Te included in the second thin film layer 130 may be composed of various ratios. In other embodiments, the second thin film layer 130 may include a phase change memory, such as Ag, In, Sb, Te (AIST). Ag, In, Sb, and Te included in the second thin film layer 130 may be combined in various ratios.

According to an embodiment, the second thin film layer 130 may include various non-volatile memristor elements. For example, the second thin film layer 130 may include a resistance change memory, a ferroelectric tunnel junction (FTJ) element using a ferroelectric material, or a magnetic random access memory (MRAM).

According to an embodiment, the phase change of the second thin film layer 130 may be achieved by heating through use of an electrical pulse between the first electrode 110 and the second electrode 140. For example, the second thin film layer 130 may be heated by a voltage pulse transferred through the filament 123 of the first thin film layer 120 to undergo a phase change between amorphous and crystal phases. Accordingly, a resistance of the second thin film layer 130 may increase or decrease according to the phase change, and may emulate a change in synaptic connection strength based on the increase or decrease in the resistance.

According to an embodiment, the second electrode 140 may be made of a metal material on which the second thin film layer 130 may be deposited. For example, the second electrode 140 may include a tungsten-titanium compound (e.g., TiW). For example, the second electrode 140 may be formed to a thickness of 35 to 45 nm.

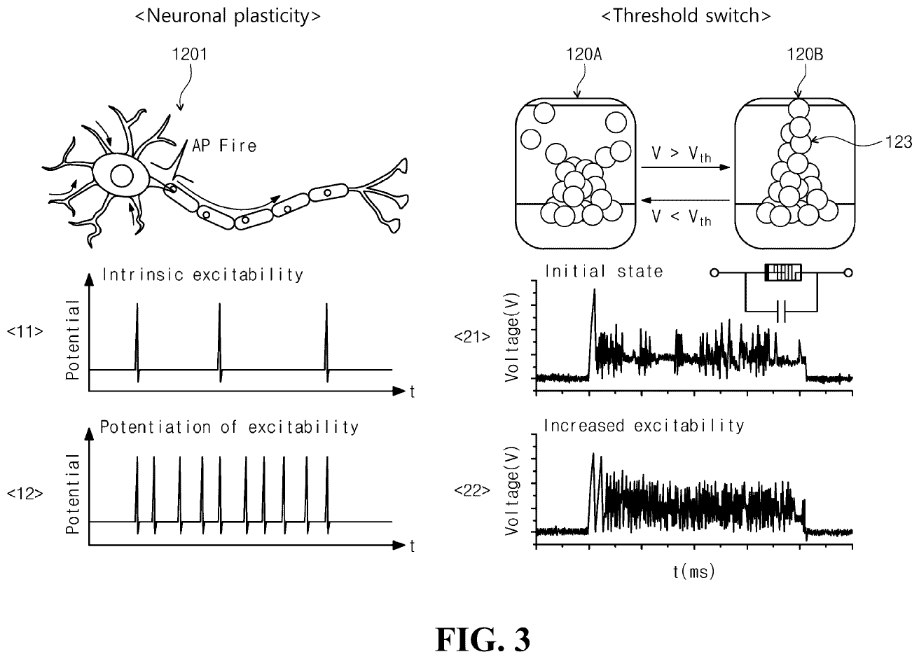

FIG. 3 is a diagram illustrating a comparison of an operation of neurons of brain cells and an operation of the first thin film layer of FIG. 1 according to an embodiment. Referring to FIG. 3, a first operation 11 and a second operation 12 may represent operations of a neuron 1201 included in human brain cells. A third operation 21 and a fourth operation 22 may represent operations of the first thin film layer 120 of FIG. 1.

According to an embodiment, the neuron 1201 may perform the first operation 11 according to an intrinsic excitability when a random stimulus is received. When the same stimulus is repeated, the neuron 1201 may perform the second operation 12 according to a potentiation of excitability. That is, when the same stimulus is repeated, a nerve transfer speed of the neuron 1201 may be increased.

According to an embodiment, in a first state 120A (e.g., an initial state) in which a voltage ‘V’ between the first electrode 110 and the second electrode 140 is less than a threshold voltage Vth, the first thin film layer 120 may not form the filament 123. In a second state 120B in which the voltage ‘V’ between the first electrode 110 and the second electrode 140 is greater than the threshold voltage Vth, the first thin film layer 120 may form the filament 123 (or a silver filament). When the voltage ‘V’ between the first electrode 110 and the second electrode 140 is less than the threshold voltage Vth and then the first thin film layer 120 returns to the first state 120A, the filament 123 of the first thin film layer 120 may be separated again.

According to an embodiment, when the neuromorphic memory element 100 and a capacitor are connected in parallel to each other, i.e., the capacitor electrodes are coupled to the first electrode 110 and the second electrode 140, respectively, the first thin film layer 120 may perform the third operation 21 and the fourth operation 22. For example, in a random state in which the voltage ‘V’ between the first electrode 110 and the second electrode 140 maintains the first state 120A less than the threshold voltage Vth for a specified time, when the voltage ‘V’ between the first electrode 110 and the second electrode 140 is greater than the threshold voltage Vth, the first thin film layer 120 may represent a tonic busting operation like the third operation 21. The third operation 21 of the first thin film layer 120 may correspond to the first operation 11 of the neuron 1201. When the second state 120B in which the voltage ‘V’ between the first electrode 110 and the second electrode 140 is greater than the threshold voltage Vth is repeated, the first thin film layer 120 may represent the tonic spiking operation like the fourth operation 22. The fourth operation 22 of the first thin film layer 120 may correspond to the second operation 12 of the neuron 1201. Thus, the first thin film layer 120 may emulate the plasticity of human neurons.

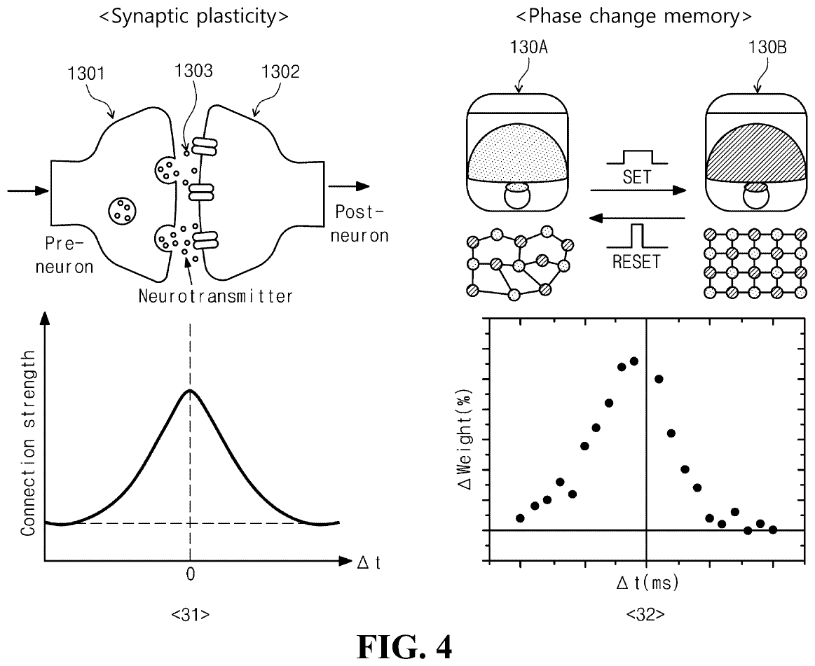

FIG. 4 is a diagram illustrating a comparison of an operation of synapses of brain cells and an operation of a second thin film layer of FIG. 1 according to an embodiment. Referring to FIG. 4, a first operation 31 may represent an operation between synapses 1301 and 1302 included in human brain cells. A second operation 32 may represent an operation of the second thin film layer 130 of FIG. 1. A synapse is a terminal for transferring information between nerve cells. This is where the interactions between an intracellular molecular network and a layer called the neuronal network take place. A plastic change in synaptic transfer efficiency is a substance of information processing in the brain. Ca ion, a major intracellular information transferer, plays an important role in synaptic plasticity, and synaptic transfer efficiency may be adjusted by controlling the electrochemical properties of neurotransmitter receptor molecules, the number of molecules, or the neurotransmitter release mechanism.

The synaptic plasticity is the dynamic control of the transfer efficiency of chemical signals at the synapse to change the transfer efficiency, and is the most basic function that realizes information processing in the brain. The neurotransmitters are dynamically modulated in release mechanisms and receptors. The efficiency of synaptic transfer has two factors. One is a change in the number of synaptic sites and the other is a change in the miniature synaptic current (mPSC) at a single synaptic site. When a synaptic area connected to an axon increases, the amplitude of the postsynaptic current induced by stimulating the presynaptic cell increases as the synaptic area increases. To predict the behavior of these elements, miniature synaptic post-currents are usually analyzed. When an action potential generation inhibitor is added to the extracellular recording solution, synaptic post-currents induced by the firing of the pre-synaptic cell disappears, and the miniature synaptic post-current (about tens of pA) is observed. It is estimated that the change in the amplitude of the miniature synaptic post-current according to the plastic change changes the sensitivity to glutamic acid at a single synaptic site. In contrast, it is thought that the change in the occurrence frequency of the miniature synaptic post-current is a change in the number of synaptic sites or an increase in the release probability of the transfer material. However, in practice, it is difficult to perform a detailed analysis only with this method because assumptions of various parameters are required. The synaptic plasticity includes a short-term potentiation (STP), a short-term depression (STD), a long-term potentiation (LTP), and a long-term depression (LTD).

According to an embodiment, two adjacent synapses (e.g., first synapse 1301 and second synapse 1302) may be connected through a neurotransmitter 1303. For example, the neurotransmitter 1303 is secreted at the terminal of the first synapse 1301 and the receptor of the second synapse 1302 receives the neurotransmitter 1303, so that a signal is transferred between the two synapses. The connection strength between two synapses may be determined according to the concentration of the neurotransmitter 1303. The connection strength between the two synapses may appear as in the first operation 31 according to the concentration of the neurotransmitter 1303.

According to an embodiment, the connection strength of the second thin film layer 130 may be determined based on the phase change state of the second thin film layer 130. For example, the phase change state of the second thin film layer 130 may be determined based on a pulse signal input between the first electrode 110 and the second electrode 140. When a set signal SET having a small voltage and a large width is input between the first electrode 110 and the second electrode 140, the second thin film layer 130 may change phases from an amorphous state 130A to a crystal state 130B. When a reset signal RESET having a large voltage and a small width is input between the first electrode 110 and the second electrode 140, the second thin film layer 130 may change phases from the crystal state 130B to the amorphous state 130A. The second operation 32 of the second thin film layer 130 may represent a similar aspect to the first operation 31 of the synapses 1301 and 1302. Thus, the second thin film layer 130 may emulate the plasticity of human neurons.

According to an embodiment, the second thin film layer 130 may emulate a spike-timing-dependent plasticity (STDP), which is a typical long-term plasticity of synapses. The second thin film layer 130 may implement a symmetric Hebbian learning rule in the STDP. The second thin film layer 130 may emulate paired-pulse facilitation (PPF), which is a typical short-term plasticity of synapses.

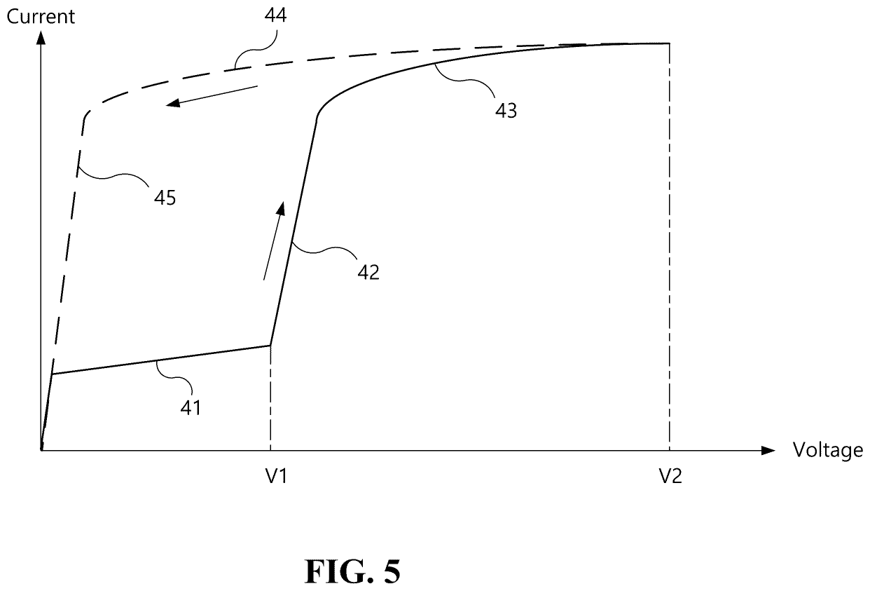

FIG. 5 is a graph illustrating a voltage and a current (or resistance state) between a first electrode and a second electrode according to a state change of a first thin film layer of FIG. 1. Referring to FIGS. 1 to 5, whether a filament is formed in the first thin film layer 120 may be determined based on a voltage between the first electrode 110 and the second electrode 140.

According to an embodiment, in a first period 41, while the voltage ‘V’ between the first electrode 110 and the second electrode 140 is less than the threshold voltage Vth, and the voltage ‘V’ between the first electrode 110 and the second electrode 140 increases, the current between the first electrode 110 and the second electrode 140 hardly increases, and the first thin film layer 120 may maintain the first state 120A (e.g., the initial state). In a second period 42, the voltage ‘V’ between the first electrode 110 and the second electrode 140 exceeds the threshold voltage Vth (e.g., V1), and even if the voltage ‘V’ between the first electrode 110 and the second electrode 140 increases slightly, the current between the first electrode 110 and the second electrode 140 increases significantly, and the first thin film layer 120 may form the filament 123 resulting in the first thin film layer 120 switching to the second state 120B. In a third period 43, while the voltage ‘V’ between the first electrode 110 and the second electrode 140 increases, the current between the first electrode 110 and the second electrode 140 hardly increases again, and the first thin film layer 120 may maintain the second state 120B.

According to an embodiment, in a fourth period 44, while the voltage ‘V’ between the first electrode 110 and the second electrode 140 decreases, the current between the first electrode 110 and the second electrode 140 hardly decreases, and the first thin film layer 120 may maintain the second state 120B. In a fifth period 45, the current between the first electrode 110 and the second electrode 140 rapidly decreases while the voltage ‘V’ between the first electrode 110 and the second electrode 140 decreases, and the first thin film layer 120 transitions to the first state 120A in which the filament 123 decomposes. As the voltage ‘V’ between the first electrode 110 and the second electrode 140 increases or decreases, the voltage and current of the first thin film layer 120 change as illustrated in the graph of FIG. 5, and accordingly, the first thin film layer 120 may be repeatedly switched between the first state 120A and the second state 120B. Accordingly, the first thin film layer 120 may operate like a volatile memory based on the voltage ‘V’ between the first electrode 110 and the second electrode 140.

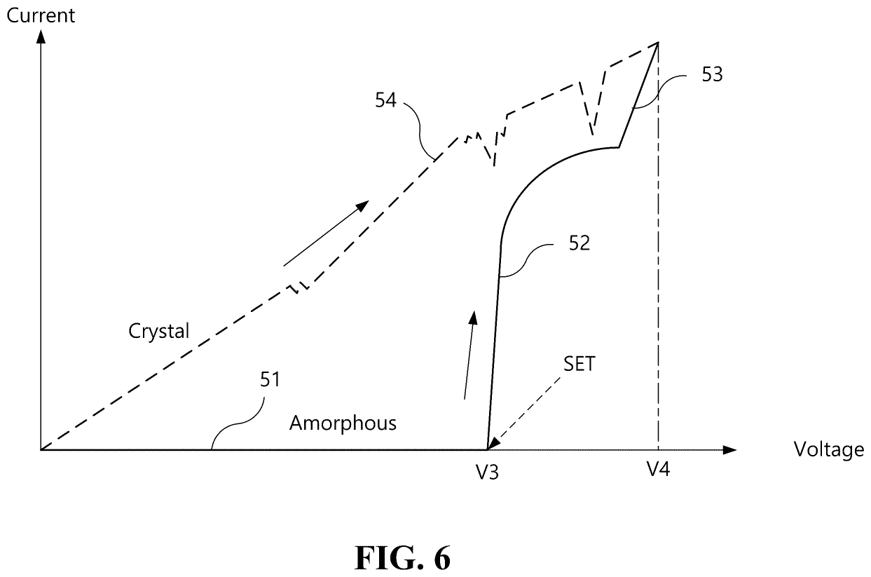

FIG. 6 is a graph illustrating a voltage and a current (or resistance state) between a first electrode and a second electrode according to a state change of a second thin film layer of FIG. 1. Referring to FIGS. 1 to 4 and 6, a phase change state of the second thin film layer 130 may be determined based on a voltage pulse applied between the first electrode 110 and the second electrode 140.

According to an embodiment, in a first period 51, the second thin film layer 130 may be in the amorphous state 130A. In the first period 51, the second thin film layer 130 may have a high resistance value. In a second period 52, when the set signal SET is applied between the first electrode 110 and the second electrode 140, the second thin film layer 130 may transition to the crystal state 130B. In the second period 52 and a third period 53, even if the voltage ‘V’ between the first electrode 110 and the second electrode 140 increases slightly, the current between the first electrode 110 and the second electrode 140 may increase significantly to follow the voltage and current graph of the crystal state 130B.

According to an embodiment, in a fourth period 54, the voltage and current of the second thin film layer 130 may move along the graph of the voltage and current in the crystal state 130B. The resistance of the second thin film layer 130 in the crystal state 130B may be less than the resistance of the second thin film layer 130 in the amorphous state 130A. Accordingly, in the crystal state 130B, the voltage and current of the second thin film layer 130 may move along a one-dimensional straight line graph. Therefore, the resistance of the second thin film layer 130 changes similarly to the operation of the synapses 1301 and 1302 according to the phase change state (e.g., the amorphous state 130A and the crystal state 130B), and the second thin film layer 130 may emulate the synaptic plasticity.

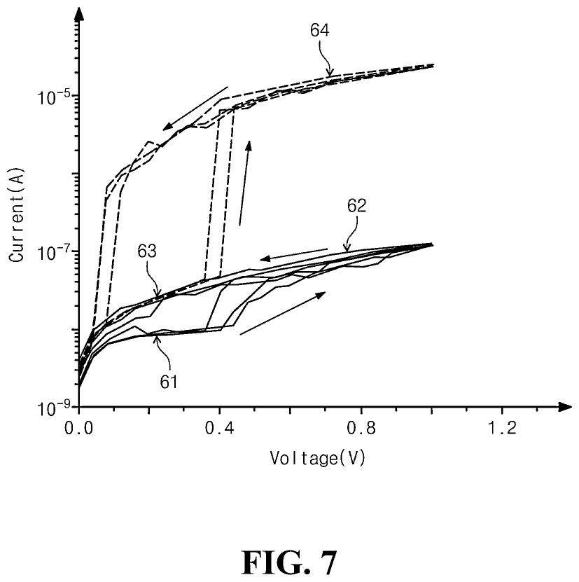

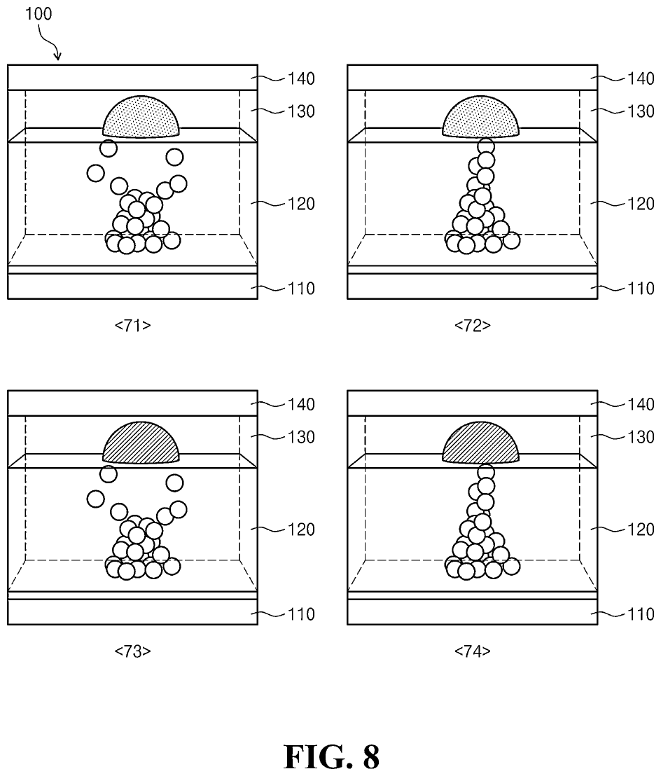

FIG. 7 is a graph illustrating a resistance state of a neuromorphic memory element of FIG. 1. FIG. 8 is a diagram illustrating states of a neuromorphic memory element of FIG. 1 corresponding to a graph of FIG. 7. Referring to FIGS. 7 and 8, the neuromorphic memory element 100 may have four resistance states 61, 62, 63, and 64. In FIG. 7, the resistance state of the neuromorphic memory element 100 may represent a form in which the resistance state of the first thin film layer 120 of FIG. 5 and the resistance state of the second thin film layer 130 of FIG. 6 interact in a complex manner. In FIG. 8, the neuromorphic memory element 100 may represent four physical property states (e.g., a first physical property state 71, a second physical property state 72, a third physical property state 73, and a fourth physical property state 74) based on an on state or off state of the first thin film layer 120 or the second thin film layer 130.

According to an embodiment, in the first resistance state 61, the first thin film layer 120 may be in an off state (e.g., the first state 120A in which filament is not formed), and the second thin film layer 130 may also be in an off state (e.g., the amorphous state 130A). In the first resistance state 61, the neuromorphic memory element 100 may have the first physical property state 71. In the second resistance state 62, the first thin film layer 120 may be in an on state (e.g., the second state 120B in which a filament is formed), and the second thin film layer 130 may be in an off state. In the second resistance state 62, the neuromorphic memory element 100 may have the second physical property state 72. In the third resistance state 63, the first thin film layer 120 may be in an off state and the second thin film layer 130 may be in an on state (e.g., the crystal state 130B). In the third resistance state 63, the neuromorphic memory element 100 may have the third physical property state 73. In the fourth resistance state 64, the first thin film layer 120 may be in an on state, and the second thin film layer 130 may also be in an on state. In the fourth resistance state 64, the neuromorphic memory element 100 may have the fourth physical property state 74.

According to an embodiment, the neuromorphic memory element 100 may simultaneously (or complexly) implement a change in volatile resistance of the first thin film layer 120 and a change in non-volatile resistance of the second thin film layer 130. For example, the first thin film layer 120 may have two resistance states depending on whether the filament is generated. In addition, the second thin film layer 130 may have two resistance states depending on whether the phase changes. Accordingly, the neuromorphic memory element 100 may have four resistance states. The first resistance state 61 may have the highest resistance when both the first thin film layer 120 and the second thin film layer 130 are in an off state (e.g., the first physical property state 71). The fourth resistance state 64 may have the lowest resistance when both the first thin film layer 120 and the second thin film layer 130 are in an on state (e.g., the fourth physical property state 74). The second resistance state 62 and the third resistance state 63 may have resistance between the first resistance state 61 and the fourth resistance state 64. Because the second thin film layer 130 is in an off state, even when the first thin film layer 120 is in an on state, the second resistance state 62 may have greater resistance than the fourth resistance state 64 (e.g., the second physical property state 72). Because the first thin film layer 120 is in an off state, even when the second thin film layer 130 is in an on state, the third resistance state 63 may have greater resistance than the fourth resistance state 64 (e.g., the third physical property state 73).

As described above, even when the same voltage is applied between the first electrode 110 and the second electrode 140, the resistance state of the neuromorphic memory element 100 may be determined differently depending on the phase change state of the second thin film layer 130. In addition, because the operation of the first thin film layer 120 is maintained according to the magnitude of the voltage applied between the first electrode 110 and the second electrode 140, volatile and non-volatile resistance changes may be implemented together or simultaneously in one neuromorphic memory element 100. Accordingly, the neuromorphic memory element 100 may simultaneously emulate features of neurons and synapses.

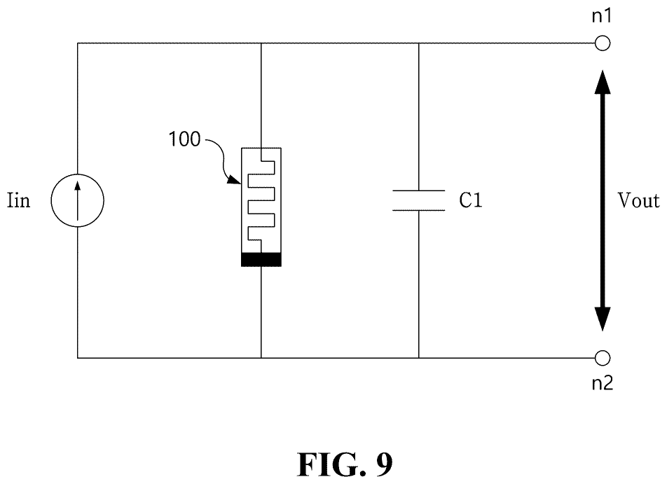

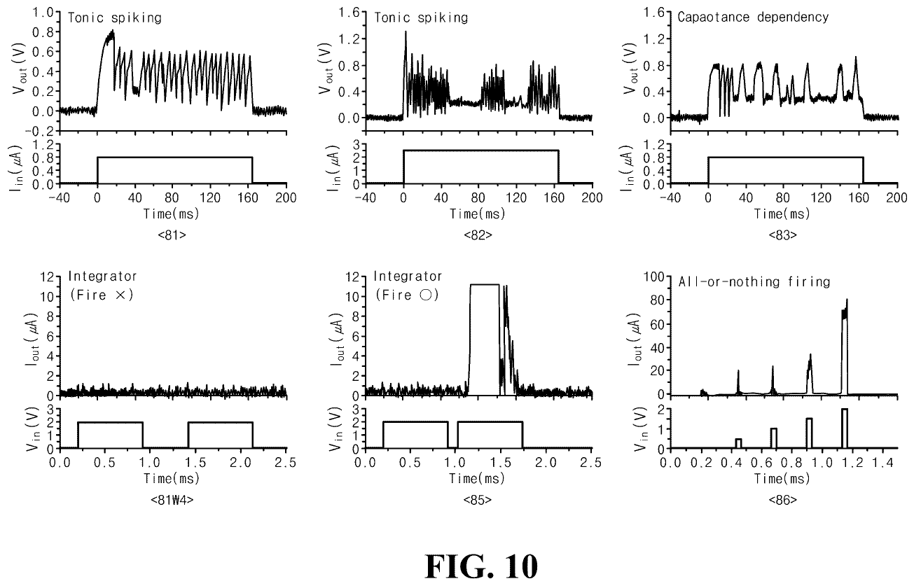

FIG. 9 is a diagram illustrating a circuit including a neuromorphic memory element of FIG. 1 for verifying a feature emulation of neurons. FIG. 10 is graphs illustrating a feature emulation of neurons verified by a circuit of FIG. 9. Referring to FIGS. 9 and 10, the neuromorphic memory element 100 may be connected in parallel with a capacitor C1 between a first node n1 and a second node n2.

According to an embodiment, when an input current Iin is applied between the first node n1 and the second node n2, an output voltage Vout between both ends (e.g., the first node n1 and the second node n2) of the neuromorphic memory element 100 may be measured. Through this output voltage Vout, it may be confirmed that the neuromorphic memory element 100 emulates firing and plasticity of neurons. Referring to a first graph 81, the neuromorphic memory element 100 may emulate tonic spiking features of neurons. Referring to a second graph 82, the neuromorphic memory element 100 may emulate tonic bursting features of neurons. Referring to a third graph 83, a frequency of the neuromorphic memory element 100 may change according to a change in capacitance.

According to an embodiment, when an input voltage Vin is applied between the first node n1 and the second node n2, an output current Iout flowing between both ends (e.g., the first node n1 and the second node n2) of the neuromorphic memory element 100 may be measured. Referring to a fourth graph 84 and a fifth graph 85, the neuromorphic memory element 100 may emulate an integrator of a leaky-integrate and fire (LIF) model, which is a representative model of neurons. Referring to a sixth graph 86, the neuromorphic memory element 100 may emulate a behavior (e.g., all-or-nothing firing) of neurons according to a working rate.

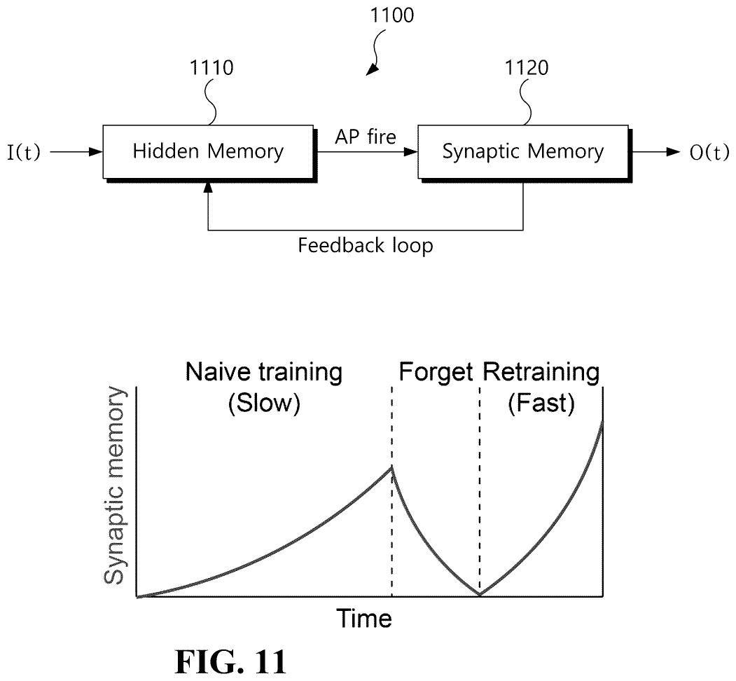

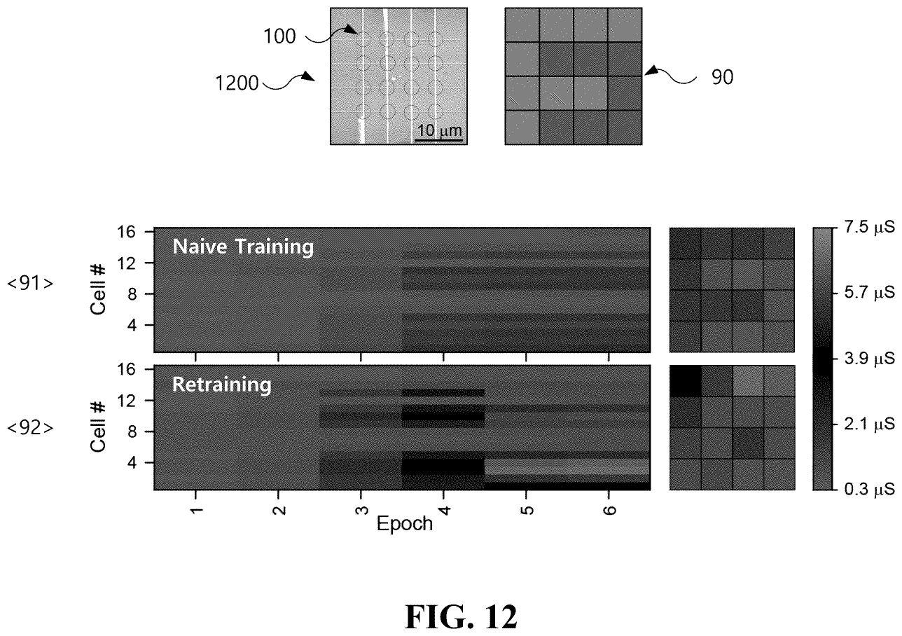

FIG. 11 is a diagram illustrating a learning process of a general spiking neural network (SNN), according to an embodiment. FIG. 12 is a diagram illustrating a learning process of a neuromorphic memory array including a neuromorphic memory element of FIG. 1. Referring to FIG. 11, a spiking neural network 1100 may include a hidden memory 1110 and a synaptic memory 1120. The hidden memory 1110 may emulate the plasticity of a neuron, and the synaptic memory 1120 may emulate the plasticity of a synapse. When the hidden memory 1110 receives an input value I(t), the hidden memory 1110 may emulate the firing of a neuron to transfer the emulated result (AP fire) to the synaptic memory 1120, and the synaptic memory 1120 may output an output value O(t) and may send feedback to the hidden memory 1110. Through this process, the spiking neural network 1100 may form a learning loop, such as reinforcement of synapses, increase in firing potential of neurons, and re-strengthening of synapses due to firing of neurons. The synaptic memory 1120 may train slowly during naive training, and then increase training speed after a designated time elapses (e.g., forget time) and during retraining. This may be similar to a training pattern of human brain cells.

Referring to FIG. 12, the neuromorphic memory element 100 may implement the spiking neural network 1100 in one element. For example, a neuromorphic memory array 1200 may be formed by configuring a plurality of neuromorphic memory elements 100 in a form of an array. As an example in FIG. 12, the neuromorphic memory array 1200 may include the neuromorphic memory elements 100 arranged in a 4×4 array.

According to an embodiment, a first training result 91 and a second training result 92 are results obtained by inputting a training pattern 90 into the neuromorphic memory array 1200. The first training result 91 is a result of obtained through naive training. The second training result 92 is a result obtained through re-training. It may be seen that, like the spiking neural network 1100, the neuromorphic memory array 1200 illustrates a more improved training speed during re-training than during naive training.

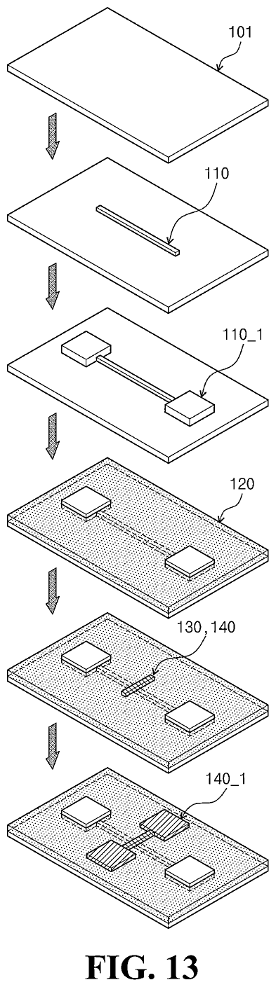

FIG. 13 is a diagram illustrating a manufacturing process of a neuromorphic memory element of FIG. 1. Referring to FIG. 13, the neuromorphic memory element 100 may have a two-terminal memristor crossbar structure.

According to an embodiment, the neuromorphic memory element 100 may have a form in which the first thin film layer 120 with a volatile feature and the second thin film layer 130 with a non-volatile feature are stacked and combined without an intermediate electrode. For example, the first electrode 110 may be formed in a bar shape on a silicon substrate 101. The first electrode 110 may be formed of gold (Au) using an e-beam lithography (EBL). In other embodiments, the first electrode 110 may be formed of a stack of gold (Au) and titanium (Ti). A first electrode pad 1101 may be formed at both ends of the first electrode 110. The first electrode pad 1101 may be formed through photolithography. The first thin film layer 120 may be formed on the first electrode 110. The first thin film layer 120 may form a silicon dioxide thin film (Ag:SiO₂) doped with silver (Ag) through co-sputtering of a silver (Ag) target and a silicon dioxide (SiO₂) target. The second thin film layer 130 may be formed on the first thin film layer 120. The GST material may be deposited on the second thin film layer 130 using the e-beam lithography (EBL). The second thin film layer 130 may be formed in a crossbar shape with respect to the first electrode 110. The second electrode 140 may be formed on the second thin film layer 130. A tungsten-titanium compound (TiW) may be deposited on the second electrode 140 using the e-beam lithography (EBL).

According to an embodiment, the neuromorphic memory element 100 may have a size of several hundred nm or less. For example, the widths of the first electrode 110 and the second electrode 140 may be determined based on conditions for repeatedly forming the filament in the first thin film layer 120. In addition, the widths of the first electrode 110 and the second electrode 140 may be determined based on the size of a region in which the second thin film layer 130 is phase-changed through the filament of the first thin film layer 120. For example, the first electrode 110 and the second electrode 140 may have a width of 100 nm or less.

According to an embodiment, the thickness of each thin film of the neuromorphic memory element 100 may have little effect on element features. However, the thickness of the neuromorphic memory element 100 may be determined in consideration of external stress on the neuromorphic memory element 100. For example, the first electrode 110 and the second electrode 140 may have a thickness of 35 to 45 nm. The source layer (e.g., the source layer 121) of the first thin film layer 120 may have a thickness of 1 to 10 nm. In other embodiments, the source layer of the first thin film layer 120 may have a thickness of 10 to 100 nm when the source layer is used as an electrode. The doped layer (e.g., the doped layer 122) of the first thin film layer 120 may have a thickness of 5 to 50 nm. The second thin film layer 130 may have a thickness of 5 to 200 nm.

According to an embodiment of the present disclosure, the plasticity of neurons and the plasticity of synapses may be simultaneously emulated by simultaneously implementing volatile and non-volatile features in a single neuromorphic memory element.

The above descriptions are specific embodiments for carrying out the present disclosure. Embodiments in which a design is changed simply or which are easily changed may be included in the present disclosure as well as an embodiment described above. In addition, technologies that are easily changed and implemented by using the above embodiments may be included in the present disclosure. While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A neuromorphic memory element comprising:
a first electrode;
a second electrode;
a first thin film layer adjacent to the first electrode between the first electrode and the second electrode, and configured to emulate a neuronal plasticity by performing a volatile storage function based on a voltage difference between the first electrode and the second electrode; and
a second thin film layer between the first thin film layer and the second electrode, and configured to emulate a synaptic plasticity by performing a non-volatile storage function.

2. The neuromorphic memory element of claim 1, wherein the first thin film layer is configured to form a filament based on a magnitude of the voltage difference applied between the first electrode and the second electrode, and wherein the second thin film layer is configured to undergo a phase change based on a voltage pulse applied between the first electrode and the second electrode.

3. The neuromorphic memory element of claim 2, wherein the first thin film layer is configured to form the filament when the voltage difference applied between the first electrode and the second electrode is greater than a threshold voltage, and to decompose the filament when the voltage difference applied between the first electrode and the second electrode is less than the threshold voltage.

4. The neuromorphic memory element of claim 2, wherein the second thin film layer is configured to change phase to a crystal state when a setting signal having a first magnitude and a first width is applied between the first electrode and the second electrode, and is configured to change phase to an amorphous state when a reset signal having a second magnitude greater than the first magnitude and a second width less than the first width is applied between the first electrode and the second electrode.

5. The neuromorphic memory element of claim 2, wherein the first thin film layer has a different rate of formation or decomposition of the filament based on a phase change state of the second thin film layer when a capacitor is connected to the first electrode and the second electrode in parallel with the first thin layer and the second thin layer.

6. The neuromorphic memory element of claim 2, wherein the second thin film layer has a different phase change rate based on whether the filament is formed in the first thin film layer when a capacitor is connected to the first electrode and the second electrode in parallel with the first thin layer and the second thin layer.

7. The neuromorphic memory element of claim 2, wherein, when the filament is not formed in the first thin film layer and the second thin film layer is in an amorphous state, the first thin film layer and the second thin film layer have a first resistance state.

8. The neuromorphic memory element of claim 7, wherein, when the filament is not formed in the first thin film layer and the second thin film layer is in a crystal state, the first thin film layer and the second thin film layer have a second resistance state less than the first resistance state.

9. The neuromorphic memory element of claim 8, wherein, when the filament is formed in the first thin film layer and the second thin film layer is in the amorphous state, the first thin film layer and the second thin film layer have a third resistance state less than the first resistance state.

10. The neuromorphic memory element of claim 9, wherein, when the filament is formed in the first thin film layer and the second thin film layer is in the crystal state, the first thin film layer and the second thin film layer have a fourth resistance state less than the second resistance state and the third resistance state.

11. A neuromorphic memory element comprising:
a first electrode;
a second electrode;
a threshold switching portion stacked on the first electrode and configured to be turned on or turned off based on a voltage difference between the first electrode and the second electrode; and
a phase change memory portion stacked between the first electrode and the threshold switching portion and configured to change phase based on a voltage pulse applied between the first electrode and the second electrode.

12. The neuromorphic memory element of claim 11, wherein the threshold switching portion comprises a thin film doped with silver (Ag) in silicon dioxide (SiO2).

13. The neuromorphic memory element of claim 12, wherein the threshold switching portion forms a silver filament to lower a resistance thereof when the voltage difference applied between the first electrode and the second electrode is greater than a threshold voltage.

14. The neuromorphic memory element of claim 11, wherein the phase change memory portion includes a GST (Ge, Sb, and Te) material or an AIST (Ag, In, Sb, and Te) material.

15. The neuromorphic memory element of claim 14, wherein the phase change memory portion is configured to change phase from an amorphous state to a crystal state to lower a resistance thereof based on the voltage pulse.

16. The neuromorphic memory element of claim 11, wherein the threshold switching portion has two resistance states based on the voltage difference between the first electrode and the second electrode, and the phase change memory portion has two resistance states based on a phase change state.

17. The neuromorphic memory element of claim 11, wherein the first electrode comprises gold (Au).

18. The neuromorphic memory element of claim 11, wherein the second electrode comprises a tungsten titanium compound.

19. A neuromorphic memory element comprising:
a first electrode;
a second electrode;
a threshold switching portion stacked on the first electrode and configured to be turned on or turned off based on a voltage difference between the first electrode and the second electrode; and
a resistance change memory portion stacked between the first electrode and the threshold switching portion and configured to change resistance based on a voltage applied between the first electrode and the second electrode.

20. The neuromorphic memory element of claim 19, wherein the threshold switching portion comprises an oxide doped with copper (Cu), and the resistance change memory portion includes a ferroelectric tunnel junction (FTJ) element using a ferroelectric or a magnetic random access memory (MRAM).
